(19) United States
(12) Patent Application Publication
(10) Pub. No.: US 2023/0393226 A1
(43) Pub. Date: Dec. 7, 2023

(54) METHOD FOR PRODUCING A SET OF CALIBRATION PADS, CALIBRATION PAD AND METHOD FOR CALIBRATING AN ELECTRON PARAMAGNETIC RESONANCE SPECTROMETER

(71) Applicant: COMMISSARIAT A L'ENERGIE ATOMIQUE ET AUX ENERGIES ALTERNATIVES, Paris (FR)

(72) Inventor: Marie-Noëlle AMIOT, Gif-Sur-Yvette Cedex (FR)

(73) Assignee: COMMISSARIAT A L'ENERGIE ATOMIQUE ET AUX ENERGIES ALTERNATIVES, Paris (FR)

(21) Appl. No.: 18/250,112

(22) PCT Filed: Oct. 21, 2021
(86) PCT No.: PCT/FR2021/051846

§ 371 Date: Apr. 21, 2023

(30) Foreign Application Priority Data
Oct. 23, 2020 (FR) 2010878

(51) Int. Cl. G01R 33/60; G01R 35/00

(52) U.S. Cl. CPC G01R 33/60; G01R 35/005

(57) ABSTRACT

A method for manufacturing a set of calibration pellets each associated with a respective absorbed dose includes, for each absorbed dose, choosing a paramagnetic material having an electron paramagnetic resonance spectrum that is stable over time, and making a first charge of the chosen paramagnetic material, the first charge having a physical parameter of which the value is equal to a target value such that a first amplitude of a first electron paramagnetic resonance spectrum of the first charge is equal to a second amplitude of a second electron paramagnetic resonance spectrum of a second charge of a predetermined dosimetric material, the second charge presenting the absorbed dose. The method also includes depositing the first charge in a cavity of a respective container formed from a material inert to electron paramagnetic resonance and sealing the cavity in a fluid-tight manner.

### TECHNICAL FIELD

The present invention relates to a method for manufacturing a set of calibration pellets for the calibration of an electron paramagnetic resonance spectrometer, each calibration pellet being associated with a corresponding absorbed dose. The invention also relates to a calibration pellet and a method for calibrating an electron paramagnetic resonance spectrometer

The invention applies to the field of measurement by electron paramagnetic resonance (EPR), in particular for the dosimetry of ionizing radiation.

### STATE OF THE ART

Spectrometry by EPR is a technique for measuring, in particular, dose absorbed by a sample, the principle of which relies on the absorption of a microwave frequency wave by a sample comprising a paramagnetic species which is placed in a magnetic field. This measuring technique gives access to a concentration of free radicals in the sample, itself representing the absorbed dose.

In conventional manner, the sample is placed in a magnetic field present within an EPR spectrometer, and is exposed to a microwave frequency electromagnetic wave of predetermined fixed frequency. Such a frequency is chosen by the manufacturer of the EPR spectrometer used, for example 9.8 GHz in the case of a so-called “X-band” spectrometer.

Next, the flux density of the magnetic field is modified. This causes the difference between the energy levels of the two spin states of the sample to vary. When this energy difference is equal to the energy of the microwave frequency electromagnetic wave (which is inversely proportional to its frequency), the microwave frequency electromagnetic wave is absorbed by the sample. Resonance in a response signal of the sample results from this. The power of the microwave frequency electromagnetic wave is chosen such that the signal-to-noise ratio of the response signal is optimal, while avoiding saturation phenomena.

A spectrum of a derivative, relative to the flux density of the magnetic field, of the response signal of the sample according to the flux density of the magnetic field is established, and the maximum amplitude of the spectrum of the derivative of the response signal (that is to say the difference between the maximum amplitude and the minimum amplitude) at a resonance of the response signal is recorded.

Another method consists of performing a spectrum fit based on a spectrum model acquired at high known dose (for example a spectrum of alanine irradiated at high dose). In this case, after adjustment of the least squares error, the spectrum to measure is equal to the reference spectrum at high dose which an adjustment coefficient multiplies. The value of the adjustment coefficient is equal to the maximum peak-to-peak amplitude sought.

This maximum amplitude is proportional to the absorbed dose by the sample. More specifically, the maximum amplitude is expressed as a dose absorbed by means of a calibration curve of the EPR spectrometer.

Such a calibration curve may be obtained by means of alanine dosimeters, irradiated in advance by means of a controlled radiation source, such that the dose absorbed by an alanine dosimeter further to such irradiation is accurately known. A measurement, by means of the spectrometer, of the maximum amplitude of the response signal corresponding to each of a plurality of alanine dosimeters, each associated with a corresponding absorbed dose, enables a calibration curve of the EPR spectrometer to be established.

Dosimeters comprising other paramagnetic dosimetric materials more dose-sensitive than alanine such as formate, lithium dithionate, phenolic compounds, or the material known by the trade name “IRGANOX° 1076” (octadecyl 3-(3,5-ditert-butyl-4-hydroxyphenyl)propanoate), may also be used.

By “dosimetric material” is understood, according to the meaning of the present invention, a material provided for the evaluation of the absorbed dose further to an irradiation by ionizing radiation.

Nevertheless, such a measuring method is not fully satisfactory. to be precise, the current quality standards (for example the standards ISO/ASTM 13304-1, ISO/ASTM 51939:2017, ISO/ASTM 51900:2009, ISO/ASTM 51702:2013) require regular calibration of spectrometers, for example twice-yearly or yearly.

Yet, in an alanine dosimeter, the radicals created by irradiation, and which are at the origin of the EPR response signal, recombine over time, leading to a loss in amplitude (also called “fading”) of the response signal. Such fading is uncontrolled, and is liable to vary from 1% per year to 3% per week, according to storage conditions.

It follows that alanine dosimeters created at a given moment in time become unusable after a certain period. Thus, a new set of alanine dosimeters must be prepared at the time of each calibration of a spectrometer, which is constraining.

Furthermore, the other dosimetric materials cited above have even lower stability than alanine, which makes their use still more constraining.

An object of the invention is thus to enable less constraining calibration of an EPR spectrometer.

### DISCLOSURE OF THE INVENTION

To that end, the invention relates to a method of the aforementioned type, and in particular to a method for manufacturing a set of calibration pellets for the calibration of an electron paramagnetic resonance spectrometer, each calibration pellet being associated with a corresponding absorbed dose, the method comprising, for each absorbed dose, the following steps:
choosing a paramagnetic material presenting an electron paramagnetic resonance spectrum that is more stable over time than an electron paramagnetic resonance spectrum of a given dosimetric material, of alanine pellet type.
weighing a first amount, referred to as first charge, of the chosen paramagnetic material, the first charge having a predetermined physical parameter of which a value is equal to a target value such that a first amplitude of a first electron paramagnetic resonance spectrum of the first charge is equal to a second amplitude of a second electron paramagnetic resonance spectrum of a second charge of the predetermined dosimetric material, said second charge presenting said absorbed dose, the second electron paramagnetic resonance spectrum being obtained in substantially the same conditions as the first electron paramagnetic resonance spectrum (the same measuring conditions target the gain setting, the wave power, the modulation amplitude, the time constant, etc. which stay fixed for several samples);
depositing the first charge in a cavity of a respective container, the container being produced from a material inert to electron paramagnetic resonance when it is subjected to a magnetic field of which the flux density belongs to a reference range for obtaining the first electron paramagnetic resonance spectrum; and
sealing the cavity of the container in fluid-tight manner.

Indeed, by virtue of such a manufacturing method, a set of dosimeters more stable than the alanine dosimeters is obtained. Each of these dosimeters is insensitive to variations in humidity and temperature, for example from −20° C. to 40° C.

In this way, it is possible to preserve the memory of a response signal of each of a set of alanine dosimeters (or comprising one or more of the dosimetric materials cited earlier), the set being in particular provided for the calibration of an EPR spectrometer.

Another advantageous aspect of the invention lies in the fact that, by virtue of their stability, such calibration pellets are capable of being exchanged between third parties with the object of making intercomparisons between laboratories, that is to say to verify the reliability of their respective instruments and the consistency between them.

Furthermore, on account of the simplicity of implementation of such a manufacturing method, the calibration pellets obtained do not suffer from the rarity or sensitivity of conventional dosimeters, such that their loss, for example when lent to a third party, causes little harm.

In the context of the invention, the manufacture of a set of calibration pellets is also advantageous for preserving the memory of the signal of the samples used in dosimetry such as the hydroxyapatite contained in dental enamel or bone tissues in accidental dosimetry (or dental dosimetry) or such as the carbonates and quartz used in dating.

According to other advantageous aspects of the invention, the method comprises one or more of the following features, taken in isolation or in any of the technically possible combinations:
the predetermined physical parameter is a mass of the first charge or an ion concentration of at least one predetermined ion in the first charge;
the paramagnetic material chosen is isotropic;
the paramagnetic material chosen is a paramagnetic material of which the magnitude of the signal does not vary over time, and advantageously comprises at least one of: a powder of magnesium oxide doped with divalent manganese ions MgO:Mn²⁺, a powder of calcium oxide doped with divalent manganese ions CaO:Mn²⁺,2,2-diphenyl-1-picrylhydrazyl, diamond nanoparticles, acrylonitrile butadiene styrene, and a powder of glass obtained by oxidation in potassium chloride;
the material inert to electron paramagnetic resonance is a plastics material, for example comprising at least one of polyoxymethylene, methyl polymethacrylate, polycaprolactone, polycarbonates.

Furthermore, the invention relates to a calibration pellet associated with a corresponding absorbed dose, the calibration pellet comprising a first charge and a respective container, the first charge being arranged in a fluid-tight cavity of the container,

the first charge being produced from a paramagnetic material having an electron paramagnetic resonance spectrum which is more stable over time than an electron paramagnetic resonance spectrum of a predetermined dosimetric material, preferably alanine.

the first charge having a predetermined physical parameter of which a value is equal to a target value such that a first amplitude of a first electron paramagnetic resonance spectrum of the first charge is equal to a second amplitude of a second electron paramagnetic resonance spectrum of a second charge of the predetermined dosimetric material, said second charge presenting said absorbed dose, the second electron paramagnetic resonance spectrum being obtained in the same conditions as the first electron paramagnetic resonance spectrum, and

the container being produced from a material inert to electron paramagnetic resonance when it is subjected to a magnetic field of which the flux density belongs to a reference range for obtaining the first electron paramagnetic resonance spectrum.
determining the absorbed dose associated with the calibration pellet, based on the measured amplitude of the calibration pellet and an equation of a calibration line established by means of dosimeters, the calibration curve associating an amplitude of an electron paramagnetic resonance spectrum with a corresponding absorbed dose.

Furthermore, the invention relates to a calibration method for calibrating an electron paramagnetic resonance spectrometer, the calibration method comprising:
for each of a plurality of calibration pellets as defined above, each associated with a distinct absorbed dose, measuring a respective calibration amplitude of a calibration electron paramagnetic resonance spectrum obtained for said calibration pellet by means of the electron paramagnetic resonance spectrometer;
determining the dose associated with each calibration pellet by means of the amplitude measured for each calibration pellet and an equation of the calibration line established from the measurement of the amplitude of the EPR spectrum of each of the dosimeters whether traceable or not, for the purpose of establishing a new stable calibration curve based on the plurality of the calibration pellets, the calibration curve associating an amplitude of an electron paramagnetic resonance spectrum with a corresponding absorbed dose.

This therefor constitutes transfer of the calibration curve established by means of dosimeters to a calibration curve established using calibration pellets that are stable over several years, thus representing the “the calibration curve memory for the dosimeters”. This may be very useful upon use of very sensitive but unstable dosimeters or for the transfer of the calibration curve to a third party whose objective is to make comparisons. The calibration curve established by means of dosimeters may be linear or non-linear.

Advantageously, the calibration pellets may be measured on any type of spectrometer from any manufacturer, knowing that the experimenter or person skilled in the art can adjust the parameters of the EPR spectrometer according to usual practices.

Advantageously, a calibration pellet may be configured to the amplitude of the sample and/or of the dosimeter to be represented either by adjusting the charge of the paramagnetic material and/or the size (height) of the container. It will be noted that the dimensions are defined in order for the parameter settings (for example, frequency and phase signal) are minimal since the dimensions are very close to those of an alanine pellet. Nevertheless, they may be modified (smaller diameter but complying with centering within the measuring tube, or greater height dimension if it is wished to increase the charge). Furthermore, the calibration pellet may be configured to the amplitude of the sample and/or of the dosimeter to represent by increasing, for example, the concentration in Mn²⁺ ion or other ion contained in its MgO or CaO matrix or other matrix. Thus, in the case of dosimeters, the dose dynamic is very great since, for example, one concentration range by mass of Mn²⁺ in MgO of 0.02% to 50% for a few tenths of a mg to several mg of the complex (without changing the dimensions of the container) allows a dose measurement range from 1 gray to at least 80000 grays.

### BRIEF DESCRIPTION OF THE DRAWINGS

The invention will be better understood with the help of the following description which is given solely by way of non-limiting example and made with reference to the accompanying drawings in which:

FIG. 1 is a diagrammatic section view of a calibration pellet according to the invention, in a longitudinal plane of the pellet

FIG. 2 is an electron paramagnetic resonance spectrum of a paramagnetic material, around a resonance of said spectrum;

FIG. 3 is a graph representing the change in a response signal of the dosimeter of FIG. 1 according to the flux density of a magnetic field to which it is subjected, the calibration pellet comprising a first charge produced from a powder of glass obtained by oxidation in potassium chloride, known as “strong pitch”; and

FIG. 4 is a graph representing the change in a response signal of the calibration pellet of FIG. 1 according to the flux density of the magnetic field to which it is subjected, the calibration pellet comprising a first charge made from a powder of magnesium oxide doped with divalent manganese ions MgO:Mn²⁺.

### DETAILED DESCRIPTION

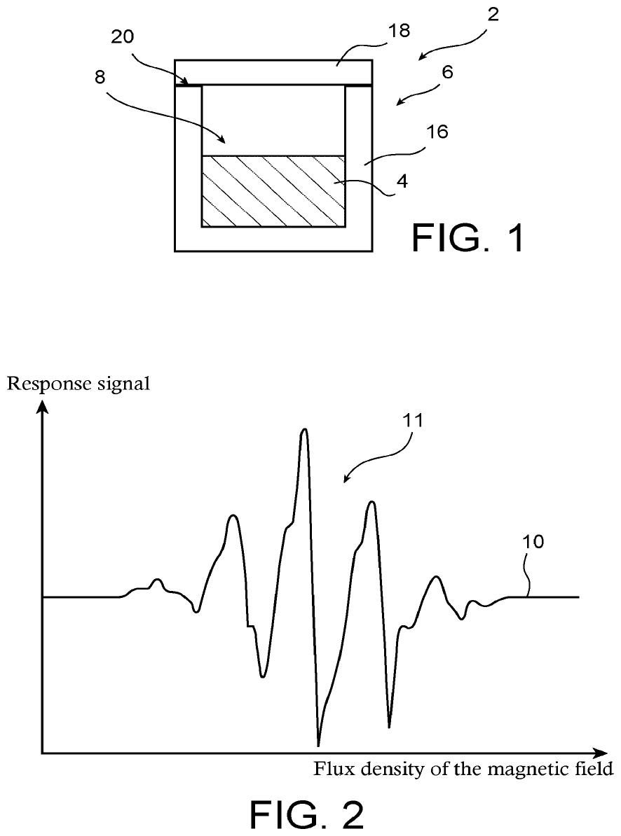

A calibration (or constancy) pellet according to the invention is illustrated by FIG. 1. It belongs to a set of calibration pellets forming a calibration group for the calibration of EPR spectrometers. Each calibration pellet of the calibration group is associated with a respective absorbed dose.

As is apparent in FIG. 1, the calibration pellet comprises a first charge 4 and a container 6. More specifically, the first charge 4 is arranged in a fluid-tight cavity 8 of the container 6. By “charge” is understood, according to the meaning of the present invention, a weighed amount and more specifically the amount of material charged into the container.

The first charge 4 is produced from a paramagnetic material having an electron paramagnetic resonance spectrum which is more stable over time than an electron paramagnetic resonance spectrum of alanine.

By “electron paramagnetic resonance spectrum” (or also “EPR spectrum”) of an object is understood, according to the meaning of the present invention, the data of the amplitude of a response signal of the object according to the flux density of the magnetic field applied to said object, when spectrometry by electron paramagnetic resonance is implemented.

By way of example, an EPR spectrum of an object produced in a paramagnetic material is illustrated by FIG. 2. In this figure, the change in the value of a response signal of the object according to the flux density of the magnetic field applied to it is represented by the curve 10. Such a curve shows the presence of a resonance 11 within a flux density range P.

Furthermore, by “paramagnetic material having an EPR spectrum more stable over time than the EPR spectrum of alanine”, is meant, according to the meaning of the present invention, a paramagnetic material for which, for each flux density of the magnetic field in a reference range, the amplitude of the EPR spectrum has a rate of decrease according to time which is lower, in absolute value, than that of the EPR spectrum of the alanine.

For example, the first charge 4 is produced from a material of which the EPR spectrum has a rate of decrease at least below, in absolute value, 2% per year, preferably 1% per year, advantageously 0.5% per year, for any magnetic field in a predetermined reference range, for example comprised between 0.336 T (tesla) and 0.364 T.

Advantageously, the paramagnetic material from which is produced the first charge 4 is isotropic, for example a powder or a ceramic.

This is advantageous, in that the EPR spectrum obtained by virtue of a calibration pellet according to the invention is invariable whatever the orientation of the dosimeter, account taken of the measurement uncertainties of the spectrometer. There is thus no call for concern about the orientation and exact positioning of the calibration pellet according to the invention upon calibration of an EPR spectrometer, or to verify the consistency of measurements between two EPR spectrometers.

For example, the paramagnetic material in which is produced the first charge 4 comprises at least one of a powder of magnesium oxide doped with divalent manganese ions MgO:Mn²⁺, a powder of calcium oxide doped with divalent manganese ions CaO:Mn²⁺,2,2-diphenyl-1-picrylhydrazyl, diamond nanoparticles, and a glass powder obtained by oxidation in potassium chloride. Such a glass powder obtained by oxidation in potassium chloride is commonly designated, according to its carbon content, by the trade term “weak pitch” or “strong pitch”.

The utilization of doped magnesium oxide MgO:Mn²⁺ is advantageous. As a matter of fact, the resonances of the response signal of a dosimeter comprising a first charge 4 produced from such a material are located on either side of the resonance of the response signal of an alanine dosimeter. Therefore, it is possible to produce a measurement simultaneously implementing an alanine dosimeter and a dosimeter comprising a first charge 4 produced from doped magnesium oxide MgO:Mn²⁺. Advantageously, it is also possible to vary the concentration of Mn2+ in the compound in addition to the charge of the container with the aim of increasing the measurement dynamic.

In this case, the calibration pellet is may serve for the monitoring of a spectrometer for instability corrections of said spectrometer, through being placed in the measuring cavity of the spectrometer, whether or not in the vicinity of a sample to measure. In this way, it is possible to dispense with a stable reference (in general, a crystal) used conventionally, that is fixed within the spectrometer to enable the stability of the signal it delivers to be monitored. This has numerous advantages; more particularly, the calibration pellet is isotropic, (in contrast to the crystal conventionally used as stable reference) and removable (it may be removed without losing the stability history).

As indicated earlier, each calibration pellet is associated with a corresponding absorbed dose.

More specifically, the first charge 4 has a predetermined physical parameter of which a value is equal to a target value such that the first amplitude of a first EPR spectrum of said first charge 4 is equal to a second amplitude of a second EPR spectrum of a second charge of alanine presenting said absorbed dose (or of a given sample to represent), the second EPR spectrum being obtained under the same conditions as the first EPR spectrum.

Such a physical parameter is, for example in particular, a mass of the first charge, and/or a concentration of a predetermined ion in the first charge 4.

For example, the first charge 4 has a target mass such that the first amplitude of the first EPR spectrum of said first charge 4 is equal to the second amplitude of said second EPR spectrum of the second charge of alanine.

Alternatively, the first charge 4 has a predetermined ion concentration (for example of Mn²⁺ ion if the first charge 4 is produced from doped magnesium oxide MgO:Mn²⁺) such that the first amplitude of the first EPR spectrum of said first charge 4 is equal to the second amplitude of said second EPR spectrum of the second charge of alanine.

In this way, the calibration pellet constitutes a memory of an alanine dosimeter (or of a given sample) for the absorbed dose or the amplitude of the EPR signal considered.

In particular, the first EPR spectrum and the second EPR spectrum are obtained for a magnetic field having a flux density belonging to the same reference range.

Such a target mass is, for example, obtained by means of charts which, for each paramagnetic material envisioned, match the mass of said paramagnetic material with a first amplitude of the corresponding EPR spectrum.

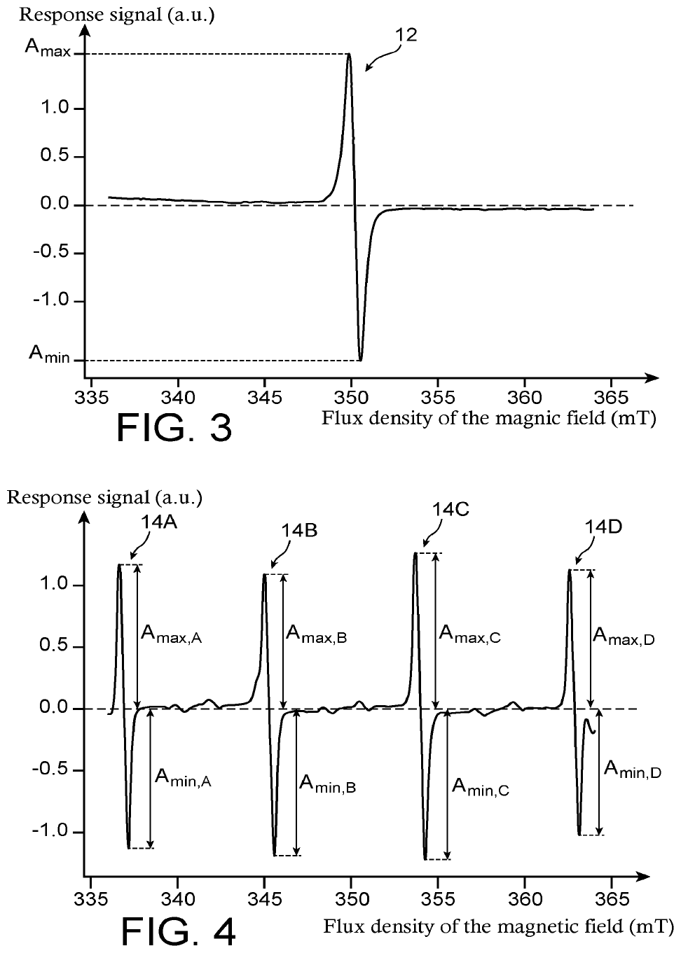

The first amplitude is, for example, chosen equal to the separation between the maximum value Aₘₐₓ and the minimum value Aₘᵢₙ (FIG. 3) taken by the response signal, at a resonance level of the response signal, for a magnetic field of which the flux density belongs to the reference range.

Such a definition is generally used when the EPR spectrum of the first charge 4 has a unique resonance. This is, for example, the case when the first charge 4 is produced from the material referred to as “strong pitch”: as is apparent in FIG. 3, the EPR spectrum of such a first charge comprises a unique resonance 12 when the flux density of the magnetic field belongs to a range comprised between 0.336 T and 0.364 T.

According to another example, when the response signal has a plurality of resonances, either the maximum amplitude of the most stable peak is chosen as first amplitude, or an average of the amplitude of several stable peaks is chosen. In this case, for each resonance A, B, C, D (FIG. 4), the corresponding amplitude is equal to the separation between the respective maximum value A_{max,A}, . . . , A_{max,D} and minimum value A_{min,A}, . . . , A_{min,D} taken by the EPR spectrum of the first charge, for a magnetic field of which the flux density belongs to the reference range.

Such a definition is generally used when the EPR spectrum of the first charge 4 has a several resonances. This is, for example, the case when the first charge 4 is designed based on a powder of magnesium oxide doped with divalent manganese ions MgO:Mn²⁺: as is apparent in FIG. 4, the EPR spectrum of such a first charge comprises, in this case, several resonances 14A-14D when the flux density of the magnetic field belongs to a range comprised between 0.336 T and 0.364 T.

Preferably, the second amplitude is taken equal to the separation between the maximum value and the minimum value taken by the response signal, at a unique resonance of the response signal of the second charge of alanine.

Furthermore, the container 6 is made from a material inert to electron paramagnetic resonance.

By “inert to electron paramagnetic resonance” is understood, according to the meaning of the present invention, that said material is a material for which the maximum amplitude of a third corresponding EPR spectrum, obtained for a magnetic field of which the flux density belongs to the reference range, is less than or equal, in absolute value, to the detection limit according to the standard “Determination of the characteristic limits (decision threshold, detection limit and limits of the confidence range) for measurements of ionizing radiation—Fundamentals and application” ISO 11929:2010.

Preferably, such a material inert to electron paramagnetic resonance is a plastics material, for example comprising at least one of polyoxymethylene, methyl polymethacrylate, polycaprolactone, polycarbonates.

As illustrated in FIG. 1, the container comprises a body 16 and a lid 18 together defining the fluid-tight cavity 8.

More specifically, the lid 18 is mounted on the body 16 and fastened thereto. Preferably, the lid 18 is bonded to the body 16 at the location of a seal 20, for example bonded thereto by means of an adhesive that is inert to electron paramagnetic resonance, for example an epoxide resin based polyepoxide known under the trade name “araldite”. In this case, the sealing of the cavity 8 is ensured by said adhesive.

Advantageously, the dimensions of the calibration pellet, in particular its transverse dimensions, are in the neighborhood of those of a conventional dosimeter produced from the predetermined dosimetric material. In this way, it is needless to greatly modify the settings of the spectrometer when replacing the conventional dosimeter by a calibration pellet according to the invention. Nevertheless, the size may be increased.

For example, in the case of a cylindrical alanine dosimeter having a height of 3 mm and a diameter of 4.8 mm, the calibration pellet has a cylindrical shape, a height of 4 mm and a diameter of 4.8 mm.

### Manufacture

The manufacture of a set of calibration pellets for the calibration of an electron paramagnetic resonance spectrometer will now be described. As indicated earlier, each calibration pellet is associated with a corresponding absorbed dose.

For each absorbed dose, the paramagnetic material from which the corresponding first charge 4 will be made is chosen.

Next, the first charge 4 is made from the chosen paramagnetic material. More specifically, the first charge 4 has a target mass such that the first amplitude of the EPR spectrum of the first charge is equal to the amplitude of an EPR spectrum for alanine presenting said absorbed dose, the two EPR spectra being obtained under the same conditions.

Next, the first charge 4 is deposited in the cavity 8 of the respective container 6, and the cavity 8 is sealed in fluid-tight manner.

To seal the cavity 8 in fluid-tight manner, an adhesive that is inert to electron paramagnetic resonance is applied at the location of the seal 20 between the body 16 and the lid 18, then the lid 18 is mounted on the body 16. Preferably, the seal is next heated (for example to 400° C.), for the purpose of making the adhesive fluid and making the container 6 melt slightly at the seal 20.

Preferably, to more accurately associate the calibration pellet with the corresponding absorbed dose, the first amplitude of the calibration pellet is measured, then associated with a specific dose of irradiation of alanine using a reference calibration curve obtained with dosimeters for example such as alanine dosimeters.

### Calibration

The calibration of an electron paramagnetic resonance spectrometer by means of a set of calibration pellets, each calibration pellet being associated with a distinct absorbed dose, will now be described.

More specifically, during such an operation, a calibration curve of the EPR spectrometer, associating an amplitude of the EPR spectrum obtained by means of said EPR spectrometer with a corresponding absorbed dose, is established.

For this, the dosimeters, each irradiated with a verified dose which is different from one dosimeter to another, are successively arranged in a measuring cavity of the EPR spectrometer, and, for each dosimeter, a corresponding EPR spectrum is acquired. Such an EPR spectrum is referred to as “calibration electron paramagnetic resonance spectrum” (or applies to calibration EPR spectrum).

Next, a calibration amplitude associated with each calibration pellet is measured based on the EPR calibration transfer spectrum. Such a calibration amplitude is obtained in similar manner to the first amplitude described above.

The absorbed dose associated with the calibration pellet is determined from the amplitude of the measured calibration pellet and from the equation of the calibration line. This operation is carried out for each calibration pellet each comprising a different paramagnetic material charge. Thus, a so-called transfer calibration curve may be established.

The number of calibration pellets is chosen according to the accuracy desired for the calibration transfer curve. Preferably, the set of dosimeters comprises at least three calibration pellets, respectively associated with doses distributed over a given range of absorbed doses. By increasing the number of calibration pellets, the accuracy of the calibration curve is increased.

Naturally, alanine may be replaced by any paramagnetic dosimetric material (or any combination of paramagnetic dosimetric materials).

Thus, the present invention relates in particular to a method for manufacturing a stable set of calibration pellets for the calibration of an electron paramagnetic resonance spectrometer, each calibration pellet being associated with a corresponding absorbed dose. The steps consisting of establishing a calibration curve using dosimeters, then of charging, into containers having dimensions close to those of an alanine pellet with a different amount of paramagnetic material which is very stable over time and of which the signal amplitude is equal, within tolerances of uncertainty, to that of each dosimeter that served to establish the calibration curve. A new calibration curve referred to as “transfer curve” is thus obtained.

The advantage lies in the stability of the calibration pellets for several years over a temperature range from −20° C. to 40° C. and their insensitivity to humidity. The measurement of calibration pellets each delivering a different stable EPR signal associated with a metrologically traceable specific absorbed dose for establishing a calibration curve as soon as required makes it possible to dispense with the irradiation of new dosimeters for which the radicals recombine over time.

The calibration pellets are removable, in contrast to the devices (in general a ruby crystal) commonly used to verify the stability of the spectrometers fixed within the measurement cavity, enabling use of the more versatile spectrometer for diverse applications.

Thus, the calibration pellets provide means for verifying the stability of EPR spectrometers, not sensitive to temperature and humidity. They enable the transfer of the calibration curves for purposes of intercomparison between laboratories since the calibration pellets may be measured on any type of EPR spectrometer with settings specific to each laboratory. They also make it possible to extend the stability verification of the signal over a very wide dynamic by a factor of 10⁵ verified by the amount of paramagnetic material and the concentration of Mn²⁺ ions for example, in the MgMn²⁺ compound. They also enable users to have a set of calibration pellets making it possible to establish an enduring, traceable calibration curve, which is a memory of the signal of the dosimeters. Another advantage of this development lies in the possibility of associating, with a set of several calibration pellets, several calibration curves corresponding to different irradiation conditions. A further possibility, regarding alanine pellets, is that a set of calibration pellets may be the memory of calibration curves produced with pellets from different suppliers, a calibration curve for lithium formate dosimeters or for instance a calibration curve of dental enamel dosings, provided that the signal amplitude of the initial samples is in the same measurement range as that of the calibration pellets.

1. A manufacturing method for manufacturing a set of calibration pellets for the calibration of an electron paramagnetic resonance spectrometer, each calibration pellet being associated with a corresponding absorbed dose,
the method comprising, for each absorbed dose:
choosing a paramagnetic material having an electron paramagnetic resonance spectrum that is more stable over time than an electron paramagnetic resonance spectrum of a predetermined dosimetric material, of alanine pellet type;
making a first charge of a chosen paramagnetic material, the first charge having a predetermined physical parameter of which a value is equal to a target value such that a first amplitude of a first electron paramagnetic resonance spectrum of the first charge is equal to a second amplitude of a second electron paramagnetic resonance spectrum of a second charge of the predetermined dosimetric material, the second charge presenting the absorbed dose, and the second electron paramagnetic resonance spectrum being obtained in the same conditions as the first electron paramagnetic resonance spectrum;
depositing the first charge in a cavity of a respective container, the container being produced from a material inert to electron paramagnetic resonance when it is subjected to a magnetic field of which a flux density belongs to a reference range for obtaining the first electron paramagnetic resonance spectrum; and
sealing the cavity of the container in a fluid-tight manner.

2. The manufacturing method according to claim 1, wherein the predetermined physical parameter is a mass of the first charge or an ion concentration of at least one predetermined ion in the first charge.

3. The manufacturing method according to claim 1, wherein the paramagnetic material is isotropic.

4. The manufacturing method according to claim 1, wherein the paramagnetic material chosen is a paramagnetic material of which a magnitude of the signal does not vary over time.

5. The manufacturing method according to claim 1, wherein the material inert to electron paramagnetic resonance is a plastics material.

6. A calibration pellet associated with a corresponding absorbed dose, the calibration pellet comprising a first charge and a respective container, the first charge being arranged in a fluid-tight cavity of the respective container,
the first charge being produced from a paramagnetic material having an electron paramagnetic resonance spectrum which is more stable over time than an electron paramagnetic resonance spectrum of a predetermined dosimetric material,
the first charge having a predetermined physical parameter of which a value is equal to a target value such that a first amplitude of a first electron paramagnetic resonance spectrum of the first charge is equal to a second amplitude of a second electron paramagnetic resonance spectrum of a second charge of the predetermined dosimetric material, the second charge presenting the absorbed dose, and the second electron paramagnetic resonance spectrum being obtained in the same conditions as the first electron paramagnetic resonance spectrum, and
the container being produced from a material inert to electron paramagnetic resonance when it is subjected to a magnetic field of which a flux density belongs to a reference range for obtaining the first electron paramagnetic resonance spectrum.

7. A calibration method for calibrating an electron paramagnetic resonance spectrometer, comprising:
for each of a plurality of calibration pellets according to claim 6, each associated with a distinct absorbed dose, measuring a respective calibration amplitude of a calibration electron paramagnetic resonance spectrum obtained for the calibration pellet using of the electron paramagnetic resonance spectrometer; and
determining the absorbed dose associated with the calibration pellet, based on the measured amplitude of the calibration pellet and an equation of a calibration line by means of using dosimeters, a calibration curve associating an amplitude of an electron paramagnetic resonance spectrum with a corresponding absorbed dose.

8. The manufacturing method according to claim 4, wherein the paramagnetic material comprises at least one of a powder of magnesium oxide doped with divalent manganese ions MgO:Mn²⁺, a powder of calcium oxide doped with divalent manganese ions CaO:Mn^{2|}, 2,2-diphenyl-1-picrylhydrazyl, diamond nanoparticles, acrylonitrile butadiene styrene, and a powder of glass obtained by oxidation in potassium chloride.

9. The manufacturing method according to claim 5, wherein the material inert to electron paramagnetic resonance comprises at least one of polyoxymethylene, methyl polymethacrylate, polycaprolactone, and polycarbonates.

10. The calibration pellet according to claim 6, wherein the paramagnetic material comprises alanine.
